(19) United States
(12) Patent Application Publication
(10) Pub. No.: US 2009/0050201 A1
(43) Pub. Date: Feb. 26, 2009

(54) SOLAR CELL

(75) Inventor: Charles M. Fortmann, Bellport, NY (US)

Correspondence Address: THE FARRELL LAW FIRM, P.C., 333 EARLE OVINGTON BOULEVARD, SUITE 701, UNIONDALE, NY, 11553, US

(73) Assignee: The Research Foundation of State University of New York, Albany, NY (US)

(21) Appl. No.: 12/175,208

(22) Filed: Jul. 17, 2008

Related U.S. Application Data
(60) Provisional application No. 60/950,234, filed on Jul. 17, 2007.
(60) Provisional application No. 61/081,492, filed on Jul. 17, 2008.
(60) Provisional application No. 61/081,494, filed on Jul. 17, 2008.

(51) Int. Cl. H01L 31/055; H01L 31/04

(52) U.S. Cl. 136/259

(57) ABSTRACT

Disclosed is a photovoltaic solar cell and method for producing same for conversion of light into electric power using a composite film having micron sized down to nanometer sized particles sufficiently sized for precise light scattering. A matrix material is further provided having a substantially different refractive index to provide a refractive index contrast for light scattering.

### PRIORITY

This application claims priority to U.S. Provisional Application No. 60/950,234, filed Jul. 17, 2007, to U.S. Provisional Application No. 61/081,492, filed Jul. 17, 2008, and to U.S. Provisional Application No. 61/081,494, filed Jul. 17, 2008, the contents of each of which are incorporated herein by reference.

### BACKGROUND OF THE INVENTION

The present invention relates to an apparatus and method for spectral modification to improve solar cell efficiency.

Photovoltaic solar cells convert light to energy via the well-known process of photo-induced electron transition from valance to conduction bands when the photon energy exceeds the energy needed by the photon to transition from the valence band to the conduction band. Fundamental quantum mechanics largely precludes the possibility of an electron being excited from the valance to the conduction band unless the photon energy is equal to or greater than the valance band to conduction band energy (known as the band gap of the material). Therefore, all photons less than the band gap of the semiconductor used to make the absorber of a solar cell are not capable of contributing to the power generation.

Conventional solar cell designs poorly convert UV photons to electrical energy since the high energy of these photons correlate to a large absorption coefficient. Therefore, Ultra Violet (UV) photons are absorbed rapidly in the solar cells regions near to surfaces and/or contacts that quickly recombine photo generated electrons and holes. Since electrons and holes need be separated and collected at the appropriate contact region in order to produce electrical power recombined electrons and holes cannot contribute to power generation.

Amorphous silicon-based solar cells have generated intense interest owing to low cost production and quick energy payback time. However, these solar cells are known to degrade under sunlight via a process involving defect formation that reduces the amount of collected (power generating) hole-electron pairs through recombination. Thin, i.e. less than 0.2 micron, amorphous silicon solar cells are degradation resistant as photo-generated carriers (electron-hole pairs) predominately reach the nearby collection electrodes even when defects are present. Thin crystalline type photovoltaic solar cells are also of interest as the reduced amount of material can significantly reduce the cost.

The absorbed layer of photovoltaic solar cells is comprised of a semiconductor material. The band gap of the material determines which photons get absorbed. (See, Fahrenbruch and Bube, Fundamentals of Solar Cells, Photovoltaic Solar Energy Conversion, Academic Press, NY 1983, p. 14.) Photons with energy less than the band gap of the absorbed light pass through without absorption and without power generation.

In both cases thin amorphous silicon and crystalline (as well as other solar cell types) thin solar cells absorb reduced amounts of light owing to well-known Beer's law for photo absorption. Since thin solar cells allow a significant portion of the above band gap (useable light) to pass through the solar cell unabsorbed.

The Beer's Law relation between the intrinsic absorption of a given material (a function of wavelength), α_{λ}, the incident photon flux, Γ_{0λ}, the light path length, L, and the unabsorbed (remaining) photon flux, Γ_{λ}, (See Fahrenbruch and Bube, Fundamentals of Solar Cells, Photovoltaic Solar Energy Conversion, Academic Press, NY 1983, p. 48) is given by Equation (1):

Γ_{λ}=Γ_{0λ}e^{-α}^{_{λ}}^{L} (1)

The long path length and/or multiple passes through a solar cell enhance absorption and power correspondingly.

Present state-of-the-art solar cells typically employ roughened front surfaces to produce a myriad of surface orientations relative to the incident light direction to scatter incident light to largest angles thereby increasing the light path beyond the thickness of the photovoltaic solar cell. See, U.S. Pat. Nos. 7,262,515, 6,653,547 and 4,021,267, the disclosure of which is incorporated herein by reference. Also, conventional systems typically to employ a light reflective layer on the back of the solar cell to reflect unused light back into the solar cell for a second chance to be absorbed. Nonetheless, a significant amount of the above-band-gap light is typically not absorbed in the thinnest solar cell types, and all of the below-band-gap light is lost in all solar cell types.

Attempts to broaden spectral response include spectral splitting multiple band gap solar cells. These and other attempts to improve solar cell performance through the engineering of the semiconductor absorber layers increase the number of processing steps, raise the device complexity, and therefore increase the solar cell cost. Furthermore, as multi-junction solar cell becomes more efficient at conversion of one particular solar spectrum (such as bight haze-less sunlight) it becomes less efficient under other conditions (for example overcast skies etc.).

Approximately 10% of the solar energy lies in a wavelength between 320 and 420 nm. In most solar cells this light is absorbed quickly. However, it is typically absorbed in support structures and/or too near to the front surface of a solar cell to produce electric power. Significantly more power is lost at longer wavelengths.

Approximately 50% of the solar energy lies between wavelengths of 720 nm (approximately the longest wavelength light a thin amorphous silicon solar cell can absorb in one or two passes) and 2 microns. Approximately 25% of the solar energy lies beyond the 1.1 micron crystalline silicon band gap and two microns. The present invention converts the unused long wavelength light to useable shorter wavelength (higher energy) light to significantly enhance performance and realize power increases.

This present invention can be realized utilizing abundant, inexpensive, and easy to manufacture vast quantities. The world consumed over 17.4 trillion-kilowatt hours of electricity in 2004. In order to provide even a significant part of this energy solar cells must be inexpensive, easy to manufacture, and contain materials and processes amenable to an unprecedented large-scale manufacturing effort.

### SUMMARY OF THE INVENTION

The present invention provides a composite film of approximately micron size crystalline silicon particles embedded in a conductive amorphous silicon-carbide film positioned on the bottom of and optically coupled to an amorphous silicon solar cell. Solar illuminated a thin (˜0.25 microns) amorphous silicon solar cell absorbs and converts visible (˜420 to 720 nm wavelength) light into electric power. Unabsorbed, predominately long wavelength, light passes through the amorphous silicon solar cell and enters the composite light scattering and spectrum-converting layer where the micron-sized silicon particles up and down convert the long wavelength light via Raman Scattering. Through scattering and reflection, the scattered and/or Raman-shifted light is reintroduced to the solar cell where the up-energy-converted portion is absorbed and thereby contributes to the electric power generated by the solar cell component.

In another embodiment, either component of the composite layer includes luminescent elements to provide spectral down-energy modification of high-energy light for a front surface application.

The present invention provides an apparatus and method to increase a path length of light by embedding small particles of spectral changing material in a matrix of high index (n>1) material on the face of a solar cell on which light is incident.

### BRIEF DESCRIPTION OF THE DRAWINGS

The above and other objects, features and advantages of certain exemplary embodiments of the present invention will be more apparent from the following detailed description taken in conjunction with the accompanying drawings, in which:

FIG. 1 shows Raman scattering as utilized in the present invention;

FIG. 2 depicts a thin film amorphous silicon solar cell and composite film of the present invention;

FIG. 3 depicts and alternative embodiment of the present invention; and

FIG. 4 provides an idealized energy level diagram of the present invention.

### DETAILED DESCRIPTION OF THE PREFERRED EMBODIMENTS

The following detailed description of preferred embodiments of the invention is provided with reference to the accompanying drawings. In describing the invention, explanation about related functions or constructions known in the art are omitted for the sake of clearness in understanding the concept of the invention, to avoid obscuring the invention with unnecessary detail.

The present invention exploits specific material properties to change the wavelength of light through an interaction involving the vibration of atoms known as Raman scattering. Raman scattering in silicon and silicon particles is particularly large.

Raman scattering can both increase and decrease photon energy a portion of an incident photon beam will be up-converted in energy. In turn these up-converted photons are useable by the solar cell component.

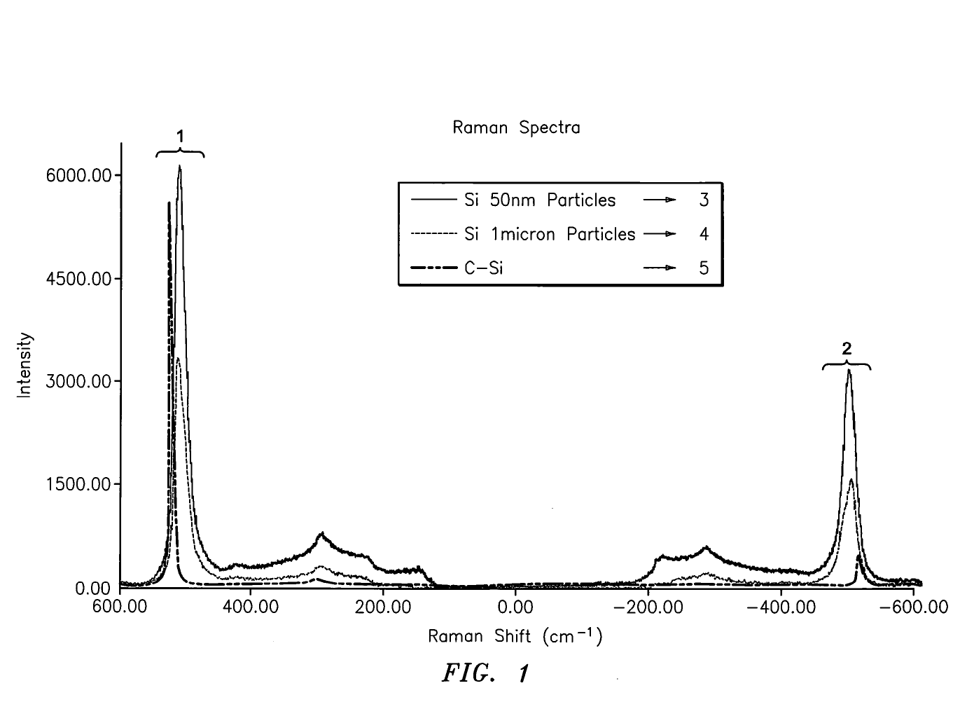

As shown in FIG. 1, Raman scattering is characterized by the interaction of light with quantized atomic vibrations within a material known as phonons. Raman-scattering occurs when a portion of the incoming photon energy is removed (down energy conversion) to form a phonon (also known as Stokes shift, shown at numeral 1 in FIG. 1. Similarly, quanta of phonon energy can be added to the incoming photon energy creating an emitted photon of higher energy (up-energy conversion), also known as anti-Stokes shift, as shown at numeral 2 in FIG. 1.

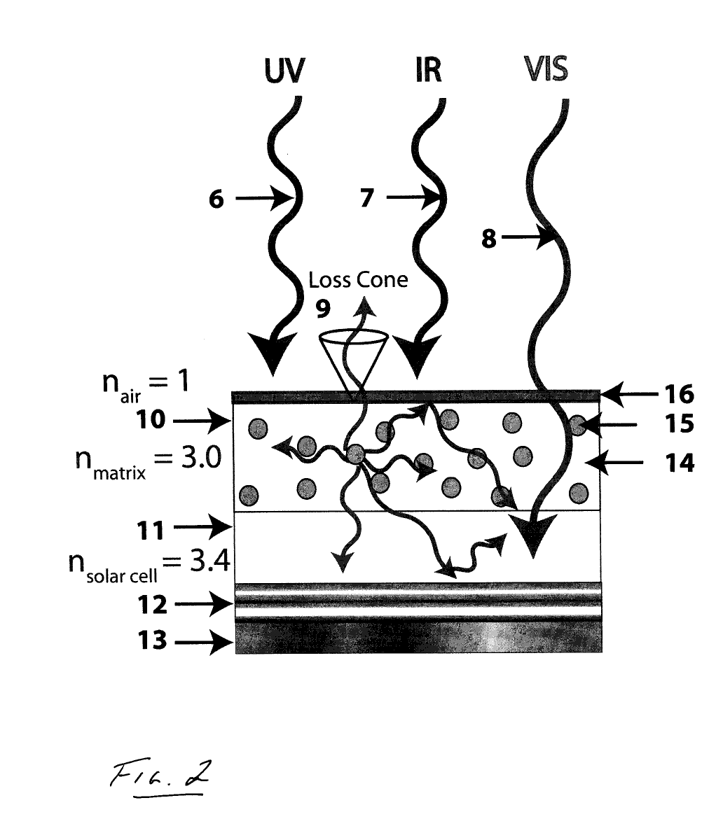

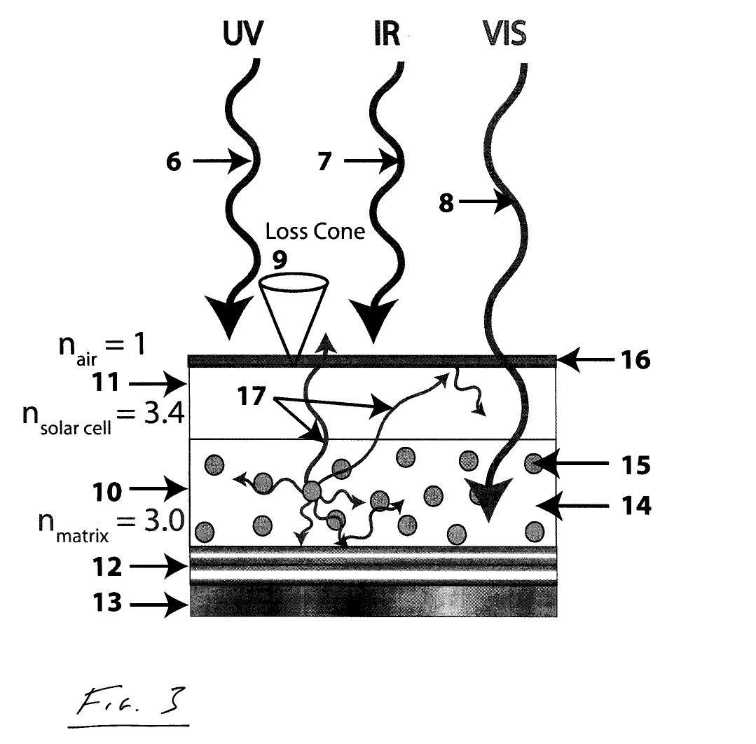

FIG. 1 shows the arrangement of spectral changing media and high index matrix for a spectral changing light scattering improvement of the present invention. Notably, a loss cone 9 (FIGS. 2 and 3) of light are scattered into angles lying within the cone are re-emitted out the front of the solar cell, without any chance to be absorbed and converted into electrical energy. The angles of the loss cone 9 are reduced (losses become smaller) with increasing media index of refraction (at appropriate wavelengths).

Commercially available phosphors (e.g., Q42 emit a visible light photon in ˜600 nm range when illuminated simultaneously in IR and visible to UV spectrum, allowing use of dispersing particles of Q 42 within a high index media for example epoxy (n=1.2) or a large band gap semiconductor (e.g., a—SiC:H with a band gap of 2.1 eV).

Important in the design of solar cells is that the light-scattering-spectral changing layer is highly conductive. When the layer is conductive, electric power can be harvested from the solar cell without the need and complexity of an underlying metal grid structure and/or conductive layer or material. Such conductivity can be realized by employing a doped semiconductor media such as p-aSiC:H material as shown in FIG. 1.

In the present invention, up-converting anti-Stokes process is predicated upon the absorption of pre-existing phonons factors that increase said pre-existing phonon density an increase of up-conversion probability is achieved. Phonon increasing factors include increasing temperature and other independent light-material interactions that generate appropriate wavelength phonons. Since silicon is an indirect band gap material, most photon absorption processes including band-to-band absorption create phonon. The present invention leverages gap illumination to increase the anti-Stokes response.

The present invention utilizes a Raman response of silicon increases with decreasing particle size, as seen in FIG. 1. There are several mechanisms contributing to this increase. Quantization considerations limit the number of phonon modes for each allowed vibration per particle. Therefore, smaller particles generate a greater probability of exciting a given (appropriately short wavelength) phonon mode per unit length traveled by a photon since the photon encounters greater numbers of particles per unit length.

Phonons cannot have a fundamental wavelength greater than their diameter. Therefore, a large part of the phonon spectrum (relative to a bulk crystal) is absent in small particles. Since phonons decay by exciting other atomic vibrations and longer wavelength phonons (the well known Umklapp process), the particle size restricted phonon spectrum leads to a longer phonon lifetime because phonon decay products are unavailable.

Previously, Fortmann (Physical Review Letters 1998) reported that the silicon band gap increased with decreasing domain (particle) size. As the band gap increases there is corresponding decrease in optical absorption. Therefore, smaller sized particles comprising a given mass will absorb less and Raman scatters with greater probabilities than larger sized particles or bulk materials.

Typically the Raman-scattering is plotted as arbitrary photon intensity as a function of reciprocal wavelength change (shift), as in FIG. 1. Importantly, relative magnitude and shift amounts are material dependent. Silicon is known to have a particularly strong Raman shift relative other materials, with a peak occurring at approximately 500 cm⁻¹.

Energy and momentum must be conserved in the light-material interaction (See Kittel, Introduction to Solid State Physics 5^{th} ed. Wiley 1976 p. 344), accordingly Equation (2) provides:

\vec{k}_{inc.photon}=\vec{k}_{scat.photon}±Kₚₕₒₙₒₙ

and

hω_{inc.photon}−hω_{scat.photon}±hωₚₕₒₙₒₙ (2)

Where |\vec{k}|=2π/λ, λ is wavelength, h is the Planck's constant, and ω is frequency. With hω_{inc.photon}−hω_{scat.photon}=Δenergy being the Raman shift in energy of an incident photon. For a Raman shift in the 10-micron range (typical for silicon), these equations indicate a phonon wavelength in the 10-nanometer range when the phonon velocity is assumed to be 10⁻³ C where C is the speed of light in the media.

Other methods for photon up-energy conversion are impractical for solar cell applications. Multi-phonon processes in some materials and elements can lead to photon up-energy conversion. However, these processes require extremely high photon fluxes (high energy beams) millions of times greater than the solar energy flux. (See N. B. Delone, V. P. Krainov, Multiphoton Processes in Atoms, Springer-Verlag, NY 1994.)

Smaller sized, as compared to those used in the present invention, ranging from 1-5 nanometers have been considered for photon down conversion via photoluminescence. (See WO/2008/051235 of Nayfeh, Munir, H. et al., the disclosure of which is incorporated herein by reference.) Since neither up-conversion processes such as the Raman-based processes described in the present invention requiring larger sized silicon nano to micro-particles, nor the described light scattering processes are employed no spectral up-conversion or enhanced long wavelength photon conversion could be realized by the Nayfeh et al. publication. Importantly the Nayef et al. publication can only be applied to the top, light incident-side, of a photovoltaic device. The silicon particle films invented here can be applied to either the top or bottom (preferred) of the photovoltaic solar cell and can employ silicon particles of much greater dimension.

Smooth, planar, optically coupled film improves solar cell performance. For example, TiO₂ particles reported by K. Winz, C. M. Fortmann, Th. Eickoff, C. Beneking, H. Wagner, H. Fujiwara, I Shimizu, Novel Light Trapping Schemes Involving Planar Junctions and Diffuse Rear Reflectors for Thin-Film Silicon-Based Solar Cells, Solar Energy Materials and Solar Cells 49, (1997) 195-203. However, Winz et al. report did not consider Raman based up-conversion.

The present invention considers that textured (rough) light scattering surface can improve the collection efficiency of amorphous silicon solar cells considerably. For example, a thin (˜250 nm) solar cell could have its light generated current increased by ˜2.5 mA an increase of greater than 15% in overall efficiency. This change is equivalent to reducing the band gap by ˜0.2 eV in its effect to enhance and extend the response of the solar cell collection to longer wavelength. Furthermore, the current gain is indicative of a large number of additional path lengths (>>2) for light within the solar cell. Accordingly, light is essentially trapped within the high index silicon.

Where solar cells are prepared by depositing films onto substrates the solar cells, junctions attain a morphology and/or roughness similar to the substrate. This, as described above, can be beneficial to light scattering and solar cell performance. For thin film deposited solar cells, rough substrate scattering mechanisms cause a junction area increase which in turn decreases solar cell performance. The maximum voltage (V_{oc}) decreases as the solar cell junction area (A) increases since, as in Equation (3):

$${V}_{oc} = γ KT ln \frac{{J}_{sc}}{{AJ}_{o}} \qquad ( 3 )$$

, where γ is the diode factor (typical between 1 and 2), K is the Boltzmann constant, T is temperature (° K), J_{sc} is the maximum light generated current, and Jₒ is the intrinsic junction leakage current. Therefore, decreasing the junction area by 50% leads to a ˜0.034 volt increase, a ˜4% increase in solar cell efficiency when the maximum voltage is taken as 0.8 Volt prior to area reduction.

A similar consideration holds for crystalline solar cells that do not attain a surface roughness dictated by substrates. Surface roughness is deliberately etched into the crystal surface to increase light absorption. The resultant surface roughness increases the surface area and, since surfaces are major photo carrier recombination loss regions, the solar cell efficiency is less than ideal.

Important to the scattering mechanism is that the silicon particles be embedded in a matrix having a refractive index as large as possible. Light traveling in large refractive index material maintains (approximately) scattering angles (or path trajectory) as it enters the optically coupled large index (e.g., silicon-based) solar cell. This consideration requires not only optical coupling but mechanical coupling as well. Thereby, light scattered large angles by the silicon particles will have a large angle and therefore long light path in the coupled solar cell.

Another method involves the addition of luminescent elemental phosphors to gain a degree of down energy conversion for enhanced short wavelength performance of the solar cell. The present invention allows for manufacture utilizing commonly available inexpensive materials, silicon particles preferably with native oxide silicon-oxide coating. These particles are combined with other particles such as silicon-carbide particles, to establish a higher refractive index for this layer, and can also be combined with a suitable binding material such as glass or transparent plastics particles melted for binding the various major constituents together.

In a preferred embodiment of the present invention, silicon particles are made conductive by inclusion of well-known impurity atoms, such as but not limited to phosphorous, arsenic, or boron, introduced through high temperature in-diffusion and/or by inclusion with silicon in solidification and/or purification processes. The transparent high refractive index component, which can be for example silicon carbide or titanium oxide, can also be made conductive through well-known processes to introduce impurities and/or defects.

In a preferred embodiment of the present invention, well-known luminescent materials such as the elements yttrium, erbium, rhenium and hafnium and other commercially available phosphors are added to above described films to down-energy convert short-wavelength high-energy light to a more useable by the solar cell longer wavelength light. Such energy down conversion compensates for the visible and ultraviolet absorption found in up-energy converting silicon particles described above when used on top of a conventional solar cell, as depicted in FIG. 2.

The materials described here are all abundant and commercially available in forms close to that required for the described invention. For example, silicon powders in 1 micron and 50 nm sizes are readily available. Sizes of silicon particles can be subsequently be manipulated by well-known etching techniques. Likewise, silicon-carbon and other potential matrix materials can also be commercially obtained. These materials can be directly mixed and fused. In some cases it might require glass and/or plastic particles and/or other relatively low melting temperature material to aid in the fusing of composite layers elements into a rigid material. Metal particles may also be added to aid fusion of materials as well as conductivity enhancement.

There are many photo detectors and other optical devices that employ semiconductor devices similar to solar cells. One example is the infrared detector based upon a small band gap solar cell or a small band gap photoconductor. Techniques that extend the performance of solar cells by up-conversion of light can be applied to these devices for extended longer wavelength performance and/or detection.

FIG. 1 shows a relative magnitude of the Raman scattered light in silicon as a function of particle size. The present invention recognizes the two Raman peaks, a Stokes-shift 1, a down energy conversion, peak and an anti-Stokes shift 2, up-energy conversion. The largest Raman scattering magnitude clearly occurs in the 50 nm particles 3 compared to the 1-micron particles 4, and the bulk silicon sample 5.

FIG. 2 illustrates a thin film amorphous silicon solar cell 11 positioned under a broad spectrum solar illumination that includes ultra violet light 6, infrared red light 7, and visible light 8. An anti-reflection coating 16 is essentially the same as the coating lens makers use to remove reflections is shown.

In a preferred embodiment, a composite planar light scattering layer 10 includes of silicon particles 15 and a matrix 14 for scattering light to large angles. Via Raman scattering, the composite planar light scattering layer 10 can convert or down convert, with approximately half of the Raman scattered light being down-converted in energy, with a Stokes-shift to longer wavelengths, and approximately half increasing in energy, with an anti-Stokes-shift to shorter wavelengths. The anti-Stokes response increases relative to the Stokes response with increasing temperature and light intensity.

In this preferred embodiment, a back reflective system is preferably provided that is prepared to reflect light back into solar cell 12. Only a small fraction of light having a large incident angle upon the internal front surface escapes the solar cell, as a consequence of Snell's law.

As shown in FIGS. 2 and 3, an angular acceptance of a loss cone 9 decreases as the refractive index of the underlying layers increase. A support structure 13 such as a substrate of amorphous silicon cell fabrication is provided. FIG. 3 shows an alternative embodiment, with the position of the composite light scattering, Raman shifting layer 10 provided beneath solar cell structure 11 as a preferred orientation.

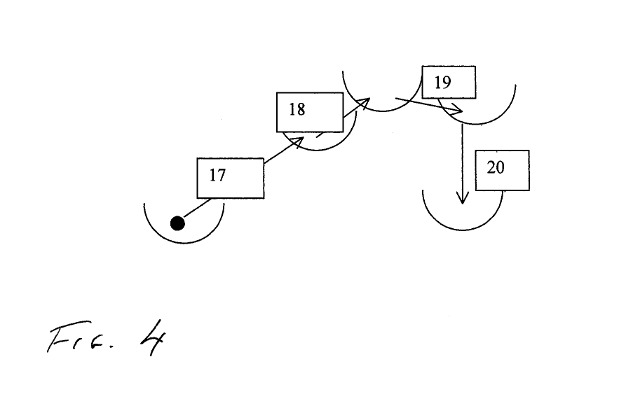

FIG. 4 illustrates a highly idealized energy level diagram for an elemental and/or commercially available phosphor for Ultra-Violet (UV) light down conversion. Here an UV wavelength photon promotes, at step 17, an electron to a first excited level. A second longer wavelength photon further promotes, at step 18, the electron to a second excited level. The electron migrates to a lower energy state, at step 19, via non-radiative processes and finally returns to its initial state via a radiative process that emits a down converted photon, at step 20.

In a preferred embodiment of the present invention, a composite film is applied to the top or bottom of a photovoltaic device, as described above in regard to FIGS. 2 and 3, to up-convert otherwise non-useable long wavelength light to a shorter wavelength, higher energy, useable light; and also to scatter visible light to large angles to improve the absorption and subsequent utilization of light energy.

The up-energy conversion is carried out by particles, such as but not limited to silicon particles, of at least 3 nm diameter via the Raman process. A film that includes silicon particles having at least 3 nm diameter and having a transparent and/or semi-transparent matrix material is preferably provided. The matrix, also referred to as a second particle type or material, is ideally transparent to visible light, conductive or semi-conductive, and has a large refractive index value relative to the semiconductor photon absorber material used in the photovoltaic device.

A relatively large refractive index and the refractive index mismatch between the matrix and the particle film form a composite light scattering and spectrum-converting layer create light scattering via processes such as Mie-scattering. For example, a preferred embodiment utilizes silicon particles having a refractive index 3.5-4.2 in a matrix of silicon-carbon, for a refractive index of ˜2.5 for the matrix, which is desirable for application to amorphous and crystalline solar cells, and band gap of >3.2 eV. In-turn scattering in combination with high refractive index traps light within the solar cell and the scattering layers, thereby causing poorly absorbed light to make numerous passes through the solar cell.

Owing to the small size and in the case of silicon particles weak absorption (˜0 for wavelengths beyond the crystal silicon band gap of 1.4 microns, ˜100 cm⁻¹ between ˜820 nm and 1.4 microns, and increasing to ˜10⁴ cm⁻¹ in the visible range) light, especially longer wavelength, can pass through the particles many times (>1000's in the case of 10 nm particles and long wavelength light) with little absorption. However, each pass raises the probability of Raman scattering.

After one pass through the solar cell, almost all of the high-energy light is absorbed in the solar cell since the absorption coefficient increases with energy in semiconductors, for energies greater than the band gap of the solar cell. Near band gap and lower energy light is poorly absorbed and therefore makes multiple passes through the stack and is trapped.

Some long wavelength light is used and converted to power by the solar cell. Some long wavelength light is lost to imperfect reflections at surfaces and some long wavelength light is lost due to the attainment of a large enough angle, relative to the plane of the front surface of the solar cell, for the light to exit the solar cell. The second loss is minimized by having in the solar cell a large refractive index and light scattering layers. Nonetheless, in the present invention long wavelength light can make an enormous number of passes through the solar cell-light scattering layer stack.

After many transits through the silicon particle (and/or other particles having sufficient Raman shift probability) the long wavelength light spectrum will be altered by the multiple Raman scattering events. This spectral alteration is analogous to a random walk in which a “dust” particle moves randomly but on average attains a distance from its initial position (in one dimension) equal to \sqrt{N}×Λ, where N is the number of hops and Λ is the hop distance. Here, the appropriate consideration is a sum of Raman up and down conversions leading to an average energy distance from the initial spectrum.

Light undergoing two Raman shifts has, on average, an energy spread that moves approximately 1.41, \sqrt{2}, times the energy per Raman shift, approximately 0.06 eV for the case of silicon particles. Half of the distribution increasing a solar cell with good conversion efficiency (e.g., an 0.25 nm amorphous silicon solar cell with effective light scattering) for wavelengths up to approximately 800 nm would realize an approximate 5% increase in its power generation due to the Raman shifts.

The solar spectrum is broad with large components of visible UV) and infrared (IR) light with peak solar energy occurring in the visible range. Efficient solar cells are necessarily designed to work in the visible spectrum. For example, the single junction amorphous silicon solar cell with a semiconductor band gap of ˜1.7 eV converts photons with wavelengths ranging from ˜480 nm to ˜720 nm with near 100% efficiency. (See Carlson in Semiconductors and Semimetals, Vol. 21, Hydrogenated Amorphous Silicon Part D, J. Pankove ed., Academic Press, NY 1984, p. 23).

One or more of the film components can be made conductive in order to allow the light conversion layer to conduct electrical current out of the photovoltaic solar cell and thereby act as a contact. Such a conducting property preferably replaces a metallic electrode contact to allow use of a smaller, less expensive and less light blocking contact. The described composite up-converting, light scattering layer is preferably prepared with sufficient rigidity to act as all or part of the a photovoltaic device support structure and/or the substrate onto which the photovoltaic cell is prepared. The present invention can be used as a coating of an existing solar cell or as a coating for a transparent substrate onto which a solar cell is to be deposited the invention can easily be incorporated into present state-of-the-art solar cell manufacture with little extra expense.

While the invention has been shown and described with reference to certain exemplary embodiments of the present invention thereof, it will be understood by those skilled in the art that various changes in form and details may be made therein without departing from the spirit and scope of the present invention as defined by the appended claims and equivalents thereof.

What is claimed is:

1. An apparatus for improved conversion of solar energy in a solar cell, the apparatus comprising:
a composite film that includes luminescent materials;
micron-sized silicon particles embedded in the film; and
a matrix,
wherein the film and matrix form a composite light scattering and spectrum-converting layer,
the film and matrix have substantially different refractive indices,
the luminescent materials convert short wavelength, high energy light, and
unabsorbed, predominately long wavelength, light passes through the solar cell and enters the composite light scattering and spectrum-converting layer for conversion by the micron-sized silicon particles.

2. The apparatus of claim 1, wherein absorption of pre-existing phonons increases a pre-existing phonon density.

3. The apparatus of claim 2, wherein absorption of pre-existing phonons increases up-conversion probability.

4. The apparatus of claim 1, wherein spectral modification down-converts short wavelength high energy light to a wavelength useable by the solar cell.

5. The apparatus of claim 1, wherein Raman Scattering converts the long wavelength light.

6. The apparatus of claim 5, wherein Raman Scattered light is reflected and reintroduced to the solar cell for absorption of an up-energy-converted portion for increased electric power generation.

7. The apparatus of claim 1, wherein the luminescent materials include one of yttrium, erbium, rhenium and hafnium.

8. The apparatus of claim 1, wherein the luminescent materials are micron to nanometer sized particles.

9. The apparatus of claim 1, wherein the matrix is a high index glass semiconductor.

10. The apparatus of claim 1, wherein the film is a conductive amorphous silicon-carbide film positioned on a bottom of an amorphous silicon solar cell, and the film is optically coupled to the solar cell.

11. The apparatus of claim 1, wherein the micron-sized silicon particles are crystalline silicon particles embedded in a conductive amorphous silicon-carbide film positioned on a bottom of and optically coupled to the solar cell.

12. The apparatus of claim 1, wherein solar illumination of solar cell results in an absorption and conversion of visible light into electric power.

13. The apparatus of claim 1, wherein a depth of the solar cell is approximately 0.25 microns.
